(19) United States
(12) Patent Application Publication
(10) Pub. No.: US 2024/0279802 A1
(43) Pub. Date: Aug. 22, 2024

(54) PROCESS CHAMBER CLEANING APPARATUS AND METHOD

(71) Applicant: Samsung Electronics Co., Ltd., Suwon-si (KR)

(72) Inventors: Jung-Min LEE, Suwon-si (KR); Gi Duck KWEON, Suwon-si (KR); Dae Ki KIM, Suwon-si (KR); Hang Kyu SONG, Suwon-si (KR); Hyun Tae YANG, Suwon-si (KR); Byoung Kwon YEO, Suwon-si (KR); Byeong Ho WOO, Suwon-si (KR); Jae Sung YU, Suwon-si (KR); Jung Bae CHOI, Suwon-si (KR)

(21) Appl. No.: 18/508,704

(22) Filed: Nov. 14, 2023

(30) Foreign Application Priority Data
Feb. 17, 2023 (KR) 10-2023-0021664
May 18, 2023 (KR) 10-2023-0064223

(51) Int. Cl. C23C 16/44; C23C 16/455

(52) U.S. Cl. CPC C23C 16/4405; C23C 16/4408; C23C 16/4557

(57) ABSTRACT

Provided are a process chamber cleaning apparatus and method in which the inside of a process chamber may be cleaned without damaging to an inner wall or a component of the process chamber. The process chamber cleaning apparatus comprising: a chamber housing; a substrate support installed inside the chamber housing, supporting a plurality of semiconductor substrates; a gas supply providing process gases; a first gas injector installed inside the chamber housing, connected to the gas supply, injecting etch gas, which is one of the process gases, into the chamber housing; and a controller controlling operations of the gas supply and the first gas injector, wherein the first gas injector injects the etch gas in a direction twisted at a predetermined angle from a central direction of the chamber housing.

### CROSS-REFERENCE TO RELATED APPLICATION

This application claims priority from Korean Patent Application No. 10-2023-0021664 and 10-2023-0064223 filed on Feb. 17, 2023 and May 18, 2023 in the Korean Intellectual Property Office and all the benefits accruing therefrom under 35 U.S.C. 119, the contents of which in their entireties are herein incorporated by reference.

### BACKGROUND

### Technical Field

The present disclosure relates to a process chamber cleaning apparatus and method, and more particularly, to a process chamber cleaning apparatus and method in which the process chamber is provided in a batch type facility.

### Description of the Related Art

A deposition process is a process of forming a material film on a semiconductor substrate, and physical vapor deposition (PVD), chemical vapor deposition (CVD), atomic layer deposition (ALD), etc. may be used as deposition methods.

However, when the deposition process is performed in a process chamber, a material film may be deposited not only on the semiconductor substrate but also on an inner wall or a component of the process chamber. Since the material film deposited on the inner wall or the component of the process chamber may act as a source of particles that contaminate the semiconductor substrate, a cleaning process for removing the material film is required.

### BRIEF SUMMARY

An object of the present disclosure is to provide a process chamber cleaning apparatus and method in which the inside of a process chamber may be cleaned without damaging an inner wall or a component of the process chamber.

However, aspects of the present disclosure are not restricted to those set forth herein. The above and other aspects of the present disclosure will become more apparent to one of ordinary skill in the art to which the present disclosure pertains by referencing the detailed description of the present disclosure given below.

In accordance with an aspect of the disclosure, a process chamber cleaning apparatus includes a chamber housing; a substrate support inside the chamber housing, the substrate support being configured to support a plurality of semiconductor substrates; a gas supply configured to provide process gases; a first gas injector inside the chamber housing and connected to the gas supply, the first gas injector being configured to inject an etch gas, which is one of the process gases, into the chamber housing; and a controller configured to control operations of the gas supply and the first gas injector, wherein the first gas injector is configured to inject the etch gas in a direction twisted at a predetermined angle from a central direction of the chamber housing, the central direction being a horizontal direction from the first gas injector to the center of the chamber housing.

In accordance with an aspect of the disclosure, a process chamber cleaning method includes, after a process of depositing a material film on a substrate is terminated, heating a chamber housing using a heating unit to adjust an internal temperature of the chamber housing; and providing an etch gas to the inside of the chamber housing using a first gas injector, wherein the first gas injector provides the etch gas in a direction twisted at a predetermined angle from a central direction of the chamber housing the central direction being a horizontal direction from the first gas injector to the center of the chamber housing.

In accordance with an aspect of the disclosure, a process chamber cleaning apparatus includes a chamber housing; a heating unit configured to heat the chamber housing to adjust an internal temperature of the chamber housing; a substrate support inside the chamber housing, the substrate support being configured to support a plurality of substrates; a gas supply configured to provide process gasses; a first gas injector inside the chamber housing and connected to the gas supply, the first gas injector being configured to inject an etch gas, which is one of the process gases, into the inside of the chamber housing; and a controller configured to control operations of the gas supply and the first gas injector, wherein the first gas injector is configured to inject the etch gas in a direction twisted at a predetermined angle from a central direction of the chamber housing, the central direction being a horizontal direction from the first gas injector to the center of the chamber housing, the first gas injector is configured to inject the etch gas in a state that the substrate support is not separated from the process chamber cleaning apparatus, the first gas injector is configured to inject the etch gas to a first zone of the chamber housing at a first time and inject the etch gas to a second zone of the chamber housing at a second time different from the first time, the etch gas includes a CIF3 component, and the heating unit is configured to adjust the internal temperature of the chamber housing to reach 150° C. to 250° C.

### BRIEF DESCRIPTION OF THE DRAWINGS

These and/or other aspects will become apparent and more readily appreciated from the following description of the embodiments, taken in conjunction with the accompanying drawings in which:

FIG. 1 is a cross-sectional view illustrating a schematic internal structure of a process chamber cleaning apparatus according to a first embodiment.

FIG. 2 is a plan view illustrating a schematic internal structure of a process chamber cleaning apparatus according to the first embodiment.

FIG. 3 is a first exemplary view illustrating various shapes of a substrate support constituting a process chamber cleaning apparatus.

FIG. 4 is a second exemplary view illustrating various shapes of a substrate support constituting a process chamber cleaning apparatus.

FIG. 5 is a plan view illustrating a schematic internal structure of a process chamber cleaning apparatus according to a second embodiment.

FIG. 6 is a cross-sectional view illustrating a schematic internal structure of a process chamber cleaning apparatus according to a third embodiment.

FIG. 7 is a plan view illustrating a plasma generating unit constituting a process chamber cleaning apparatus according to the third embodiment.

FIG. 8 is a first exemplary view illustrating a temperature condition of the process chamber cleaning apparatus.

FIG. 9 is a second exemplary view illustrating a temperature condition of the process chamber cleaning apparatus.

FIG. 10 is a first exemplary view illustrating various structures of the first gas injector constituting the process chamber cleaning apparatus.

FIG. 11 is a second exemplary view illustrating various structures of a first gas injector constituting a process chamber cleaning apparatus.

FIG. 12 is a third exemplary view illustrating various structures of a first gas injector constituting a process chamber cleaning apparatus.

FIG. 13 is a first exemplary view illustrating an operating method of a first gas injector when a first gas injector has a structure according to the first embodiment.

FIG. 14 is a second exemplary view illustrating an operating method of a first gas injector when a first gas injector has a structure according to the first embodiment.

FIG. 15 is a third exemplary view illustrating an operating method of a first gas injector when the first gas injector has a structure according to the first embodiment.

FIG. 16 is a first exemplary view illustrating an operating method of a first gas injector when a first gas injector has a structure according to the second embodiment.

FIG. 17 is a second exemplary view illustrating an operating method of a first gas injector when a first gas injector has a structure according to the second embodiment.

FIG. 18 is a third exemplary view illustrating an operating method of a first gas injector when a first gas injector has a structure according to the second embodiment.

FIG. 19 is a first exemplary view illustrating an operating method of a first gas injector when the first gas injector has a structure according to the third embodiment.

FIG. 20 is a second exemplary view illustrating an operating method of a first gas injector when the first gas injector has a structure according to the third embodiment.

FIG. 21 is a third exemplary view illustrating an operating method of a first gas injector when the first gas injector has a structure according to the third embodiment.

FIG. 22 is a flow chart sequentially illustrating a process chamber cleaning method of a process chamber cleaning apparatus.

### DETAILED DESCRIPTION OF THE DISCLOSURE

Hereinafter, example embodiments of the present disclosure will be described in detail with reference to the accompanying drawings. The same components in the drawings will be denoted by the same reference numerals, and an overlapping description thereof will be omitted.

The present disclosure relates to a process chamber cleaning apparatus and method, in which a material film deposited on an inner wall or on a component of a process chamber may be removed. First, the process chamber cleaning apparatus will be described.

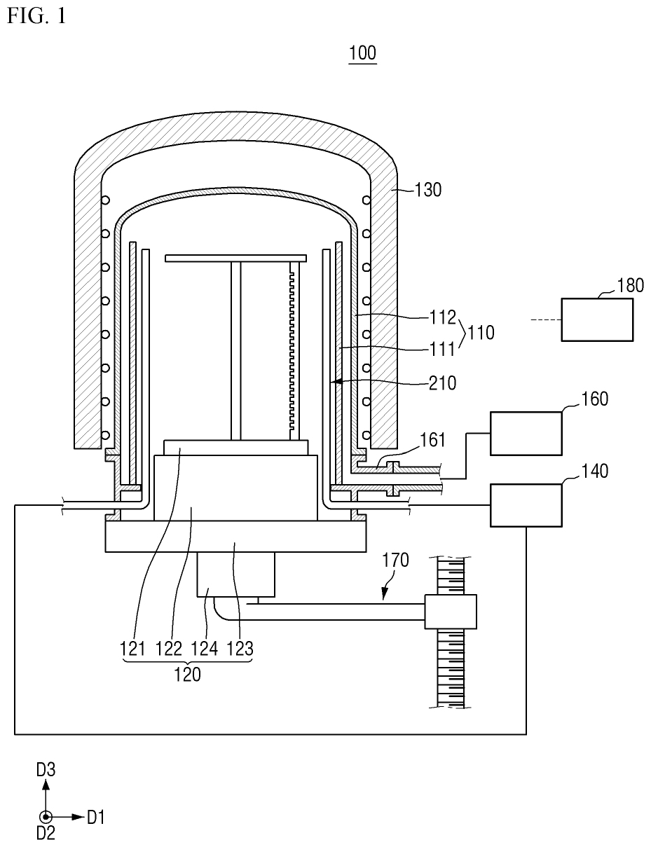

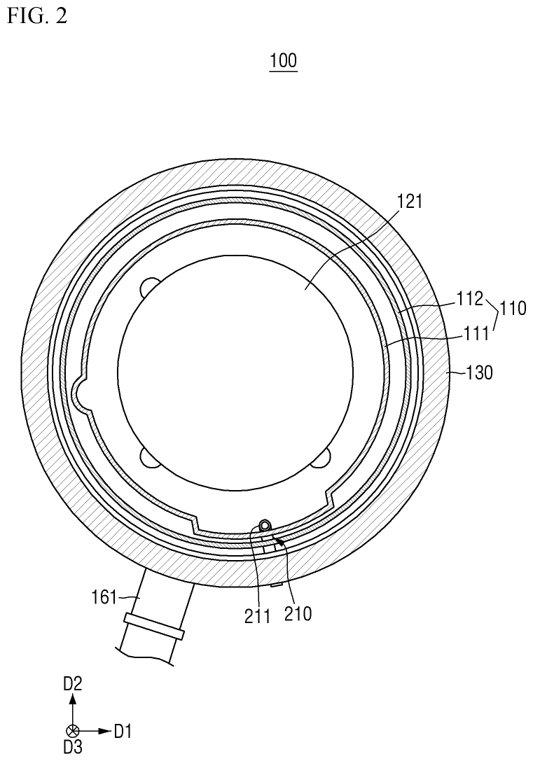

FIG. 1 is a cross-sectional view illustrating a schematic internal structure of a process chamber cleaning apparatus according to the first embodiment. FIG. 2 is a plan view illustrating a schematic internal structure of a process chamber cleaning apparatus according to the first embodiment.

Referring to FIGS. 1 and 2, a process chamber cleaning apparatus 100 may include a chamber housing 110, a substrate support 120, a heating unit 130, a gas supply 140, a gas discharge unit 160, an elevating unit 170, a controller 180, and a first gas injector 210.

The process chamber cleaning apparatus 100 is an apparatus for cleaning a process chamber, and may remove a material film deposited on an inner wall or on a component of a process chamber. For example, the process chamber cleaning apparatus 100 may remove the material film deposited on a surface of an inner tube 111 or an outer tube 112, which constitutes the chamber housing 110. In addition, the process chamber cleaning apparatus 100 may remove the material film deposited on a surface of a support plate 122 or on a substrate loading member 121, which constitutes the substrate support 120. In addition, the process chamber cleaning apparatus 100 may remove the material film deposited on a surface of the first gas injector 210.

The process chamber cleaning apparatus 100 may process a semiconductor substrate through a deposition process. The process chamber cleaning apparatus 100 may deposit the material film on the semiconductor substrate. The process chamber cleaning apparatus 100 may deposit the material film on the semiconductor substrate by using an atomic layer deposition (ALD) method, but the present invention is not limited thereto. For example, the process chamber cleaning apparatus 100 may deposit the material film on the semiconductor substrate by using a physical vapor deposition (PVD) method or a chemical vapor deposition (CVD) method.

The process chamber cleaning apparatus 100 may be a batch type facility. The process chamber cleaning apparatus 100 may deposit the material film on a plurality of semiconductor substrates simultaneously.

Although described above, the material film may be deposited not only on the semiconductor substrate but also on the inner wall or on the component of the process chamber. The process chamber cleaning apparatus 100 may deposit the material film on the semiconductor substrate, and then may remove the material film deposited on the inner wall or on the component of the process chamber.

The chamber housing 110 may provide a space in which the substrate is processed. The chamber housing 110 may be made of a material having excellent high temperature resistance and corrosion resistance. For example, the chamber housing 110 may be made of yttrium oxide (Y₂O₃). Alternatively, the chamber housing 110 may be made of quartz or silicon carbide (SiC).

The chamber housing 110 may include the inner tube 111 and the outer tube 112. The inner tube 111 may be provided in a cylinder shape with an open top and bottom. For example, the inner tube 111 may be provided in a circular ring shape. The outer tube 112 may be formed to surround the inner tube 111. For example, the outer tube 112 may be provided in a shape of a cylindrical tube having a closed upper portion. The outer tube 112 may have an open bottom like the inner tube 111.

The substrate support 120 may be disposed inside the chamber housing 110. The substrate support 120 may support a plurality of substrates. The substrate support 120 may arrange the plurality of substrates in a vertical direction (a third direction D3) and support the plurality of substrates arranged as above, but the invention is not limited thereto. The substrate support 120 may arrange the plurality of substrates in a horizontal direction (a first direction D1 or a second direction D2) and support the plurality of substrates arranged as above.

The substrate support 120 may include a substrate loading member 121, a support plate 122, a seal cap member 123, and a rotating member 124.

The substrate loading member 121 may be disposed on the support plate 122 inside the chamber housing 110. The substrate loading member 121 may load the plurality of substrates. For example, the substrate loading member 121 may load 25 or 50 substrates. The substrate loading member 121 may be provided as a boat capable of loading the plurality of substrates.

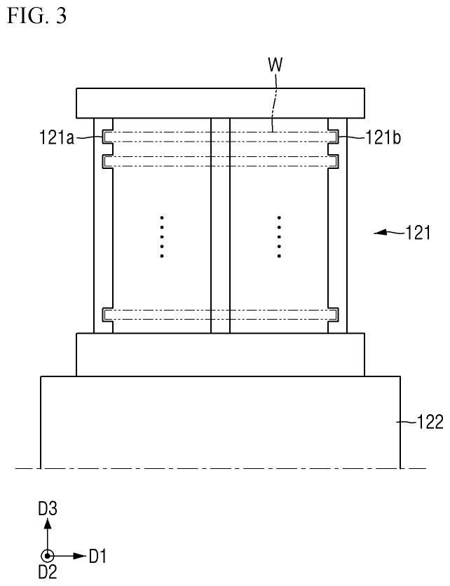

As shown in FIG. 3, the substrate loading member 121 may stack a plurality of substrates W in the vertical direction D3, and may load the plurality of substrates W in this state. The substrate support 120 may include the substrate loading member 121 shown in FIG. 3 to support the plurality of substrates W arranged in the vertical direction D3. FIG. 3 is a first exemplary view illustrating various shapes of a substrate support constituting a process chamber cleaning apparatus.

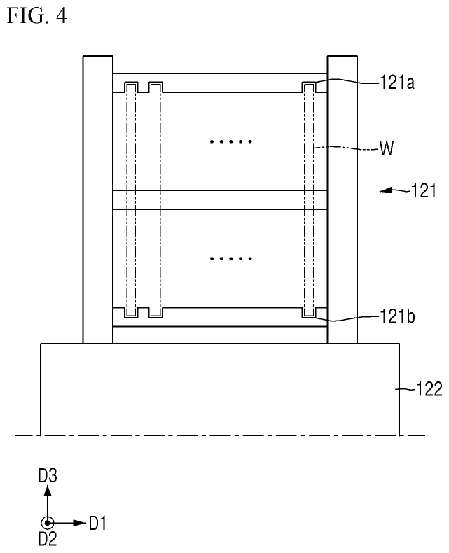

However, the invention is not limited to the above example, and as shown in FIG. 4, the substrate loading member 121 may align the plurality of substrates W in the horizontal direction (D1 or D2) and load the plurality of substrates W in this state. The substrate support 120 may include the substrate loading member 121 shown in FIG. 4 to support the plurality of substrates W arranged in the horizontal direction (D1 or D2). FIG. 4 is a second exemplary view illustrating various shapes of a substrate support constituting a process chamber cleaning apparatus.

The substrate loading member 121 may include a plurality of slots to load the plurality of substrates W. Each slot may include a pair of slot grooves 121a and 121b into which the substrate W is inserted, and the number of slots may correspond to the number of substrates W that may be loaded. However, in some examples, and the substrate loading member 121 may include only one set of slot grooves or may include three or more sets of slot grooves.

The substrate loading member 121 may be made of a material having excellent high temperature resistance. For example, the substrate loading member 121 may be made of quartz or silicon carbide (SiC).

The following description will be given with reference to FIGS. 1 and 2 again.

The elevating unit 170 may elevate the substrate loading member 121. For example, the elevating unit 170 may be a motor, an actuator, or the like. The substrate loading member 121 may be loaded or unloaded inside the chamber housing 110 under the control of the elevating unit 170. The substrate loading member 121 may be loaded into the chamber housing 110 when processing the plurality of substrates, and may be unloaded from the inside of the chamber housing 110 when processing of the plurality of substrates is completed.

The support plate 122 may support the substrate loading member 121. The support plate 122 may be coupled to the substrate loading member 121 and the seal cap member 123, and may be loaded or unloaded inside the chamber housing 110 under the control of the elevating unit 170 like the substrate loading member 121.

The seal cap member 123 may be disposed below the support plate 122, and may seal the opened lower portion of the inner tube 111 and the outer tube 112. The seal cap member 123 may move in the vertical direction (the third direction D3) under the control of the elevating unit 170. The vertical direction is the same direction as the loading direction of the plurality of substrates W when the plurality of substrates W are loaded on the substrate loading member 121 as shown in FIG. 3.

A sealing member may be provided at a portion where the seal cap member 123 and the outer tube 112 are in contact with each other. For example, the sealing member may be provided as an O-ring. The sealing member may prevent gas from leaking through a space between the chamber housing 110 and the seal cap member 123.

The rotating member 124 includes a rotary motor, and may rotate the substrate loading member 121. The rotating member 124 may rotate the seal cap member 123, thereby causing the substrate loading member 121 to be rotated. The rotating member 124 may be installed to be connected to the seal cap member 123 and the elevating unit 170. For example, the seal cap member 123 may be provided as a turn table.

However, the invention is not limited to the above example, and the rotating member 124 may rotate the support plate 122, thereby causing the substrate loading member 121 to be rotated. The rotating member 124 may be installed to be connected to the support plate 122 and the seal cap member 123 between the support plate 122 and the seal cap member 123. The rotating member 124 may indirectly rotate the substrate loading member 121 by using the support plate 122 or the seal cap member 123, but may directly rotate the substrate loading member 121.

Although not shown in FIGS. 1 and 2, the inner tube 111, the outer tube 112 and the seal cap member 123 may be coupled to a concentrically disposed manifold. The inner tube 111 and the outer tube 112 may be fixed to the seal cap member 123 via the manifold. The manifold has a cylindrical shape with an open top and bottom, and may be made of a metal (e.g., steel) material.

The heating unit 130 may be installed to surround the chamber housing 110. The heating unit 130 may heat the chamber housing 110. The heating unit 130 may heat the chamber housing 110 such that the internal temperature of the chamber housing 110 conforms to a predetermined condition.

Clean gas (CG) may not spontaneously react with a reactant. In this case, the reactant refers to the material film deposited on the inner wall or on the component of the process chamber. For example, the reactant means a material film deposited on a surface of a component constituting the chamber housing 110, a material film deposited on a surface of a component constituting the substrate support 120, and the like. To react the clean gas (e.g., cleaning gas) with the reactant, enthalpy may be required. The enthalpy may be energy required to dissociate positive ions and negative ions of the clean gas from each other. The heating unit 130 may supply thermal energy to react the clean gas with the reactant. The heating unit 130 may heat the chamber housing 110 to supply energy having the same value as the enthalpy or energy having a value greater than the enthalpy to the clean gas. The heating unit 130 may cause the clean gas and the reactant to react with each other.

The gas supply 140 may provide process gas to the first gas injector 210. The gas supply 140 and the first gas injector 210 may be connected to each other through a supply line. The process gas provided to the first gas injector 210 by the gas supply 140 may include the clean gas.

The first gas injector 210 may be disposed in the chamber housing 110. The first gas injector 210 may inject the process gas provided by the gas supply 140 into the chamber housing 110. The first gas injector 210 may inject the process gas in various ways.

The first gas injector 210 may inject the clean gas for removing the reactant generated by source gas and reaction gas into the chamber housing 110. The clean gas may be injected into the chamber housing 110, so that the inner wall or the component of the process chamber may be cleaned. A cleaning process may be performed in situ in a state that the chamber housing 110 and/or the substrate support 120 is not separated.

The clean gas may etch the reactant deposited on the chamber housing 110 and/or the substrate support 120. The clean gas may be etch gas capable of expediting reaction with the reactant. The clean gas may be etch gas containing a halogen component. For example, the clean gas may include at least one component, such as ClF₃ (chlorine trifluoride), CF₄, Cl₂F₂, Cl₃F, CClF₃, CCl₂F₂, CCl₃F, C₂F₆, C₂F₆ and C₃F₈, but the invention is not limited thereto. The clean gas may also include at least one component such as Cl₂, BCl₃, ChxCly (where, x, y=0 to 4), and SiHxCly (where, x, y=0 to 4).

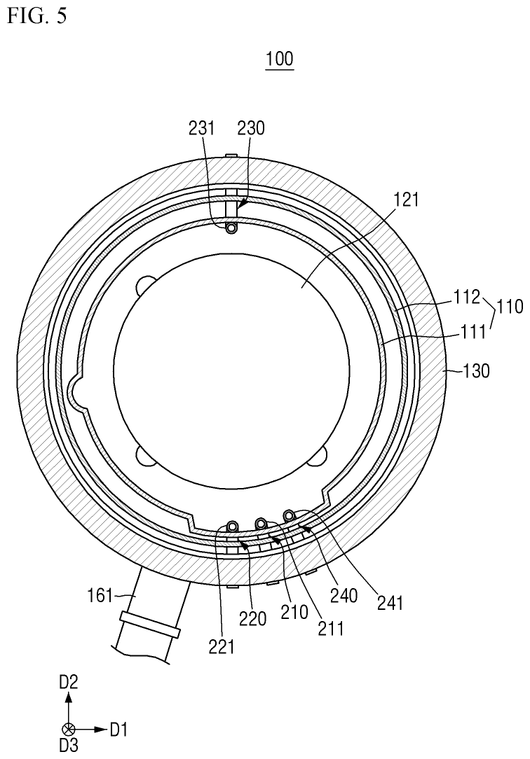

The process chamber cleaning apparatus 100 may further include a second gas injector 220, a third gas injector 230, and a fourth gas injector 240. FIG. 5 is a plan view illustrating a schematic internal structure of a process chamber cleaning apparatus according to the second embodiment. Hereinafter, the description will be given with reference to FIG. 5.

The second gas injector 220, the third gas injector 230, and the fourth gas injector 240 may be disposed in the chamber housing 110. The gas supply 140 may provide the process gas to the second gas injector 220, the third gas injector 230 and the fourth gas injector 240. The second gas injector 220, the third gas injector 230 and the fourth gas injector 240 may be connected to the gas supply 140 through a supply line. The process gas provided to the second gas injector 220 by the gas supply 140 may include source gas. The process gas provided to the third gas injector 230 by the gas supply 140 may include reaction gas. The process gas provided to the fourth gas injector 240 by the gas supply 140 may include chemical gas.

The second gas injector 220 may inject the source gas into the chamber housing 110. The second gas injector 220 may be disposed to be adjacent to an exhaust port 161. The second gas injector 220 may include a source nozzle 221 extended to be long in the vertical direction D3. The source nozzle 221 may be provided in the inner tube 111 of the chamber housing 110. The source nozzle 221 may be disposed between the substrate loading member 121 and the inner tube 111.

The third gas injector 230 may inject the reaction gas reacting with the source gas into the chamber housing 110. The reaction gas may react with the source gas to produce a reactant. The reactant may be deposited on the semiconductor substrate W to form a thin film (material film). The reactants may be deposited on the inner wall or the component of the process chamber as well as the semiconductor substrate W. For example, the reactant may be polysilicon.

The third gas injector 230 may be installed to be spaced apart from the second gas injector 220. For example, the third gas injector 230 may be installed to face the second gas injector 220 with the substrate loading member 121 interposed therebetween. The third gas injector 230 may include a reaction nozzle 231 extended to be long in the vertical direction D3. The reaction nozzle 231 may be provided in the inner tube 111 of the chamber housing 110. The reaction nozzle 231 may be disposed between the substrate loading member 121 and the inner tube 111.

In the present disclosure, a liquid source material may be provided to form a thin film on the semiconductor substrate W. In this case, the gas supply 140 may include a vaporizer for vaporizing the liquid source material. When the liquid source material is vaporized, the second gas injector 220 may inject the source gas into the chamber housing 110.

The fourth gas injector 240 may inject purge gas for purifying the inside of the chamber housing 110 into the chamber housing 110. For example, the purge gas may be chemical gas for removing the clean gas from the inside of the chamber housing 110. The chemical gas may be reacted with the clean gas to remove the clean gas remaining after the cleaning process.

When the process chamber cleaning apparatus 100 further includes the second gas injector 220, the third gas injector 230 and the fourth gas injector 240, the first gas injector 210 may be installed to be adjacent to the second gas injector 220. The first gas injector 210 may include a cleaning nozzle 211 extended to be long in the vertical direction D3. The cleaning nozzle 211 may be provided in the inner tube 111 of the chamber housing 110. The cleaning nozzle 211 may be disposed between the substrate loading member 121 and the inner tube 111. A plurality of cleaning nozzles 211 may be provided. In this case, some cleaning nozzles may be disposed between the substrate loading member 121 and the inner tube 111. Further, some other cleaning nozzles may be disposed between the inner tube 111 and the outer tube 112.

The fourth gas injector 240 may be installed to be adjacent to the first gas injector 210, but the invention is not limited thereto, and the fourth gas injector 240 may be also installed to be adjacent to the second gas injector 220. In this case, the first gas injector 210 and the fourth gas injector 240 may be disposed on both sides of the second gas injector 220 with the second gas injector 220 interposed therebetween. The fourth gas injector 240 may include a purge nozzle 241 extended to be long in the vertical direction D3. The purge nozzle 241 may be provided in the inner tube 111 of the chamber housing 110. The purge nozzle 241 may be disposed between the substrate loading member 121 and the inner tube 111.

The first gas injector 210, the second gas injector 220, the third gas injector 230 and the fourth gas injector 240 may be made of a material having excellent high temperature resistance. For example, the first gas injector 210, the second gas injector 220, the third gas injector 230 and the fourth gas injector 240 may be made of quartz or silicon carbide (SiC).

Although described above, the first gas injector 210 and the fourth gas injector 240 may be installed to be adjacent to the second gas injector 220, but the invention is not limited thereto. The first gas injector 210 and the fourth gas injector 240 may be also installed to be adjacent to the third gas injector 230. Alternatively, either one of the first gas injector 210 and the fourth gas injector 240 may be installed to be adjacent to the second gas injector 220, and the other injector may be installed to be adjacent to the third gas injector 230.

The description will be given with reference to FIGS. 1 and 2 again.

The gas discharge unit 160 may discharge the gas in the chamber housing 110 to the outside. The gas discharge unit 160 may decompress an internal pressure of the chamber housing 110. The gas discharge unit 160 may include an exhaust port 161 and a pump, which are provided in the chamber housing 110. Although not shown in FIG. 1, the exhaust port 161 and the pump may be connected to each other by a vacuum tube.

The controller 180 may control the operation of each component constituting the process chamber cleaning apparatus 100. For example, the controller 180 may control a rotation speed and elevation of the semiconductor substrate W loaded on the substrate loading member 121. To this end, the controller 180 may control the operation of the rotating member 124 and the elevating unit 170. The controller 180 may control the internal temperature of the chamber housing 110. To this end, the controller 180 may control the operation of the heating unit 130. The controller 180 may adjust the type, supply flow rate, and supply time of the process gas provided to an inner space of the chamber housing 110. To this end, the controller 180 may control the operations of the gas supply 140, the first gas injector 210, the second gas injector 220, the third gas injector 230 and the fourth gas injector 240. The controller 180 may adjust the internal pressure of the chamber housing 110. To this end, the controller 180 may control the gas discharge unit 160.

The controller 180 may be configured to include one or more modules related to a function or an operation for controlling each component constituting the process chamber cleaning apparatus 100. The module may be provided in the form of an application or a program, and may be implemented by a command language stored in a computer-readable recording medium (for example, a hard disk, a portable disk such as a CD-ROM or a DVD, a semiconductor memory such as a flash memory, etc.). When the command language is executed by a processor, the processor may perform a function corresponding to the command language. The command language may include a code generated by a compiler or a code that may be executed by an interpreter. The controller 180 may be provided as a computing device for communicating with each component constituting the process chamber cleaning apparatus 100 through a wired/wireless network for information processing, data provision, and the like.

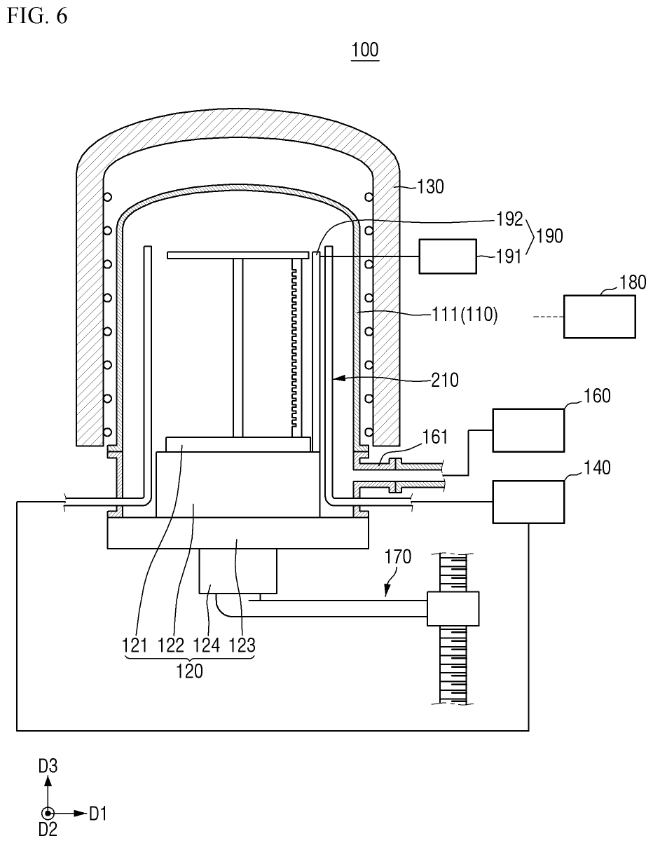

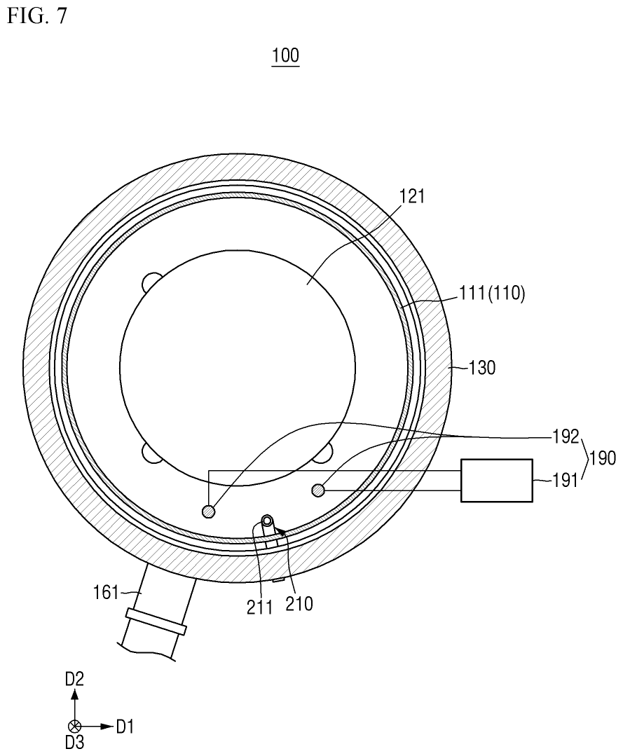

FIG. 6 is a cross-sectional view illustrating a schematic internal structure of a process chamber cleaning apparatus according to the third embodiment. FIG. 7 is a plan view illustrating a plasma generating unit constituting a process chamber cleaning apparatus according to the third embodiment.

Referring to FIGS. 6 and 7, the process chamber cleaning apparatus 100 may include a chamber housing 110, a substrate support 120, a heating unit 130, a gas supply 140, a gas discharge unit 160, an elevating unit 170, a controller 180, a first gas injector 210, and a plasma generating unit 190. Hereinafter, description will be omitted for a redundant portion with the case of FIG. 1, and only a portion corresponding to the difference will be described.

The chamber housing 110 may include only the outer tube 112. That is, unlike the example of FIG. 1, the chamber housing 110 may not include the inner tube 111.

The plasma generating unit 190 may excite the clean gas to supply energy to the clean gas. For example, the plasma generating unit 190 may supply energy to the clean gas so as to dissociate CCl₄ contained in the clean gas into cations of C and anions of Cl. The plasma generating unit 190 may generate plasma from the clean gas. The cations of C and the anions of Cl, which are dissociated, may easily react with the reactant.

The plasma generating unit 190 may include electrodes 192 disposed inside the chamber housing 110 and an external power source 191 for applying a power source to the electrodes 192. The electrodes 192 may be spaced apart from each other. The electrodes 192 may be disposed on both sides of the cleaning nozzle 211 with the cleaning nozzle 211 interposed therebetween (see, e.g., FIG. 7). When the power source is applied to the electrodes 192, the clean gas may be excited to be in a plasma state.

As the demand for memory semiconductors has been increased recently, many facilities are being operated in semiconductor FAB to cope with the demand. As a result, the number of engineers required for operation is also increasing significantly. However, since manpower is not actively supplied, it is necessary to respond to the demand by reducing the maintenance work hours of the engineers. Therefore, a technology for automatically maintaining semiconductor fabricating facilities is required.

The main maintenance work of the semiconductor fabricating facility is to remove the membrane (e.g., material film) accumulated inside the facility during the process. The present disclosure describes a process chamber cleaning apparatus 100 that removes reactants deposited on the inner wall or the component of the process chamber due to the deposition process for the semiconductor substrate by using the etch gas.

The process chamber cleaning apparatus 100 may automatically remove the reactant deposited on the inner wall or the component of the process chamber without manual labor by an engineer. To this end, the process chamber cleaning apparatus 100 may include a controller 180. The controller 180 may significantly reduce the maintenance work time of the engineer by automatically executing the maintenance work of the process chamber.

The process chamber cleaning apparatus 100 may remove the reactant deposited on the inner wall or the component of the process chamber without disassembling the component. For example, the process chamber cleaning apparatus 100 may simultaneously clean the chamber housing 110, the substrate support 120, and the like by using the etch gas without removing the substrate loading member 121 on the support plate 122. The process chamber cleaning apparatus 100 may remove the reactant deposited on the inner wall or the component of the process chamber without damaging the inner wall or the component of the process chamber.

The process chamber cleaning apparatus 100 may use a gas containing ClF3 component as the etch gas. The first gas injector 210 may inject the etch gas containing the ClF3 component to the inside of the chamber housing 110, and the process chamber cleaning apparatus 100 may remove the reactant deposited on the inner wall or the component of the process chamber through reaction between the etch gas and the reactant.

In the present disclosure, it is possible to increase a selectivity of Si component and SiC component by improving a cleaning condition of the ClF3 component. In this case, the Si component may be an element constituting the reactant. In addition, the SiC component may be an element constituting the component of the process chamber. For example, the SiC component may be an element constituting the substrate support 120 or the like.

The process chamber cleaning apparatus 100 may increase reaction between the etch gas and the reactant (e.g., the Si component). The process chamber cleaning apparatus 100 may reduce reaction between the etch gas and the element constituting the inner wall of the process chamber (e.g., the SiC component). When the reaction between the etch gas and the reactant is defined as a first reaction, and the reaction between the etch gas and the element constituting the inner wall of the process chamber is defined as a second reaction, the process chamber cleaning apparatus 100 may increase the first reaction so that the frequency of occurrence of the first reaction is greater than the frequency of occurrence of the second reaction. The process chamber cleaning apparatus 100 may increase the first reaction so that when the second reaction occurs once, the first reaction occurs 100 times or more. Preferably, the process chamber cleaning apparatus 100 may increase the first reaction so that when the second reaction occurs once, the first reaction may occur at least 100 to 180 times and up to 250 to 300 times.

The process chamber cleaning apparatus 100 may increase the frequency of the first reaction so that the frequency of occurrence of the first reaction is higher than the frequency of occurrence of the second reaction, so that the inner wall or the component of the process chamber may not be damaged even though the reactant deposited on the inner wall or the component of the process chamber is removed without disassembling the component.

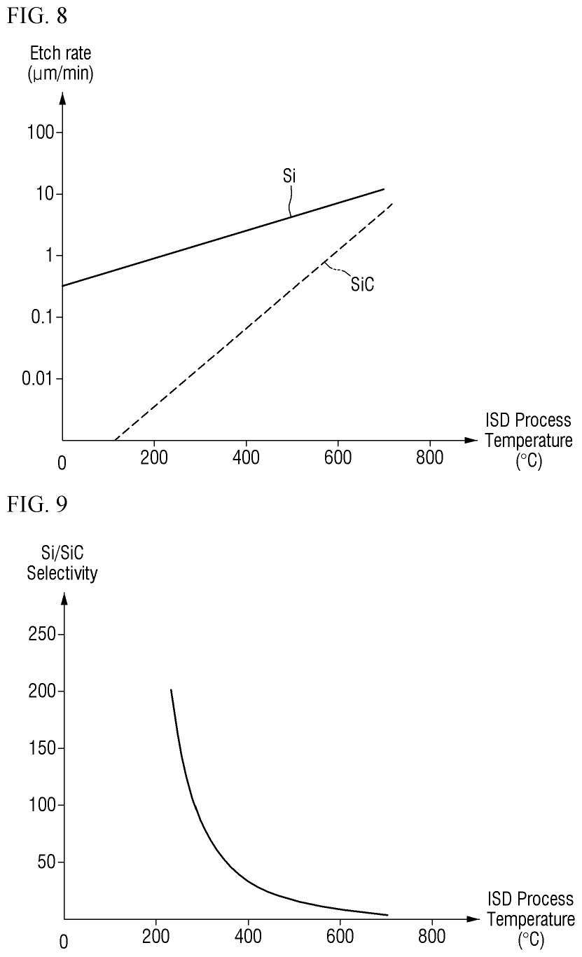

The process chamber cleaning apparatus 100 may increase the frequency of occurrence of the first reaction by allowing the internal temperature of the chamber housing 110 to satisfy a predetermined condition. The internal temperature of the chamber housing 110 may be adjusted by the heating unit 130. Referring to FIGS. 8 and 9, as an in-situ dry cleaning (ISD) process temperature is lowered, it may be noted that an etch rate of SiC is significantly lower than that of Si. Therefore, it may be noted that Si/SiC selectivity (e.g., a ratio of a frequency of occurrence between the Si etch rate and the SiC etch rate) is increased. However, when the ISD process temperature is lowered, the ISD process time may be increased.

The ISD process temperature (i.e., the internal temperature of the chamber housing 110) may be determined in consideration of an appropriate ISD process time (i.e., an appropriate cleaning time for the inner wall or the component of the process chamber). The process chamber cleaning apparatus 100 may increase the frequency of occurrence of the first reaction by maintaining the internal temperature of the chamber housing 110 at 150° C. to 250° C. Preferably, the process chamber cleaning apparatus 100 may increase the frequency of occurrence of the first reaction by maintaining the internal temperature of the chamber housing 110 at 250° C. FIG. 8 is a first exemplary view illustrating a temperature condition of the process chamber cleaning apparatus, and FIG. 9 is a second exemplary view illustrating a temperature condition of the process chamber cleaning apparatus.

The first gas injector 210 may inject the etch gas into the chamber housing 110 in order to remove the reactant deposited on the inner wall or the component of the process chamber. The first gas injector 210 may be positioned on one side of the inside of the chamber housing 110, and at this position, may inject the etch gas toward the center of the inside of the chamber housing 110. However, in view of the airflow of the etch gas, it may be noted that the airflow is concentrated on one side, whereby it is likely that local over-etching or non-uniform etching may occur.

In order to solve such a problem in the present disclosure, a spiral nozzle, a 2-way 2-hole nozzle, a 2-way multi-hole nozzle and the like may be applied to the first gas injector 210. The first gas injector 210 may be provided as a multi-way multi-hole nozzle.

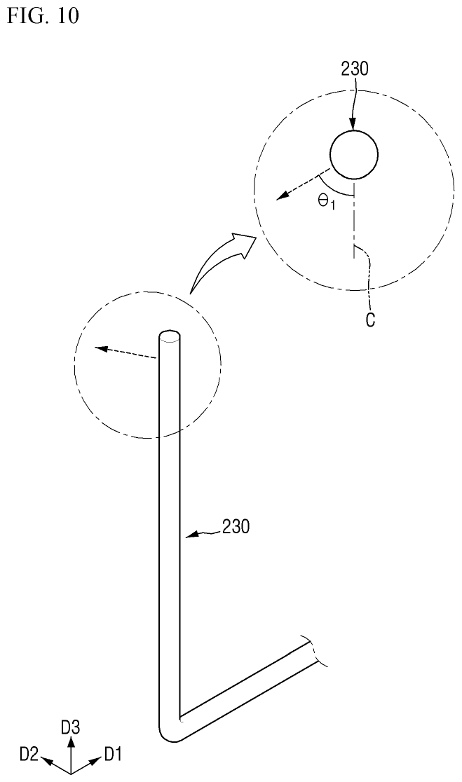

First, a case that the first gas injector 210 is provided as a spiral nozzle will be described. FIG. 10 is a first exemplary view illustrating various structures of the first gas injector constituting the process chamber cleaning apparatus.

The first gas injector 210 may include a first injection hole. The first injection hole of the first gas injector 210 may inject the etch gas in a direction out of the center of the inside of the chamber housing 110. The first injection hole of the first gas injector 210 may inject the etch gas in a direction twisted at a first angle 01 from a central direction C of the inside of the chamber housing 110. For example, the central direction C may be a horizontal direction from the position of the first gas injector 210 to the center of the chamber housing 110. The first angle θ₁ may be greater than 0° and smaller than 90°. Preferably, the first angle θ₁ may be greater than 45° and smaller than 90°. More preferably, the first angle θ₁ may be greater than 60° and smaller than 80°. More preferably, the first angle θ₁ may be 70°.

It should be appreciated that ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first” in a particular claim) may be described elsewhere with a different ordinal number (e.g., “second” in the specification or another claim).

The first injection hole may be formed toward the direction twisted at the first angle θ₁ from the central direction of the chamber housing 110. Therefore, the first injection hole may inject the etch gas in the direction away from the center of the inside of the chamber housing 110, but the invention is not limited thereto. The first injection hole may be formed to be rotated in the direction twisted at the first angle 01 from the central direction of the chamber housing 110.

The first gas injector 210 may be provided as a spiral nozzle, thereby improving concentration uniformity of the etch gas in the chamber housing 110. In addition, as the first gas injector 210 is provided as a spiral nozzle, a flow rate may be improved so that the speed of airflow in the chamber housing 110 is increased.

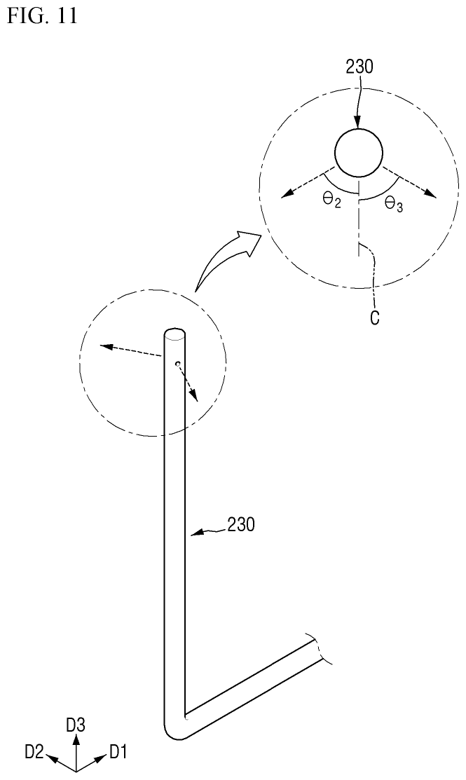

Next, a case that the first gas injector 210 is provided as a 2-way 2-hole nozzle will be described. FIG. 11 is a second exemplary view illustrating various structures of a first gas injector constituting a process chamber cleaning apparatus.

The first gas injector 210 may include a first injection hole and a second injection hole. The first injection hole and the second injection hole of the first gas injector 210 may inject the etch gas in different directions away from the center of the inside of the chamber housing 110. The first injection hole of the first gas injector 210 may inject the etch gas in the direction (e.g., a first direction) twisted at a second angle θ₂ in one direction from the central direction C of the inside of the chamber housing 110. The second injection hole of the first gas injector 210 may inject the etch gas in the direction (e.g., a second direction) twisted at a third angle θ₃ from the central direction C of the inside of the chamber housing 110 to the other side direction.

The second angle θ₂ and the third angle θ₃ may be greater than 0° and smaller than 90°. Preferably, the second angle θ₂ and the third angle θ₃ may be greater than 45° and smaller than 90°. More preferably, the second angle θ₂ and the third angle θ₃ may be greater than 60° and smaller than 80°. More preferably, the second angle θ₂ and the third angle θ₃ may be 70°. The second angle θ₂ and the third angle θ₃ may be the same value, but the invention is not limited thereto, and the second angle θ₂ and the third angle θ₃ may be different values.

The first injection hole may be formed to be twisted at the second angle θ₂ from the central direction of the chamber housing 110 to one side direction (e.g., a first direction). Therefore, the first injection hole may inject the etch gas in the direction away from the center of the inside of the chamber housing 110, but the invention is not limited thereto, and the first injection hole may be rotatably formed to be twisted at the second angle θ₂ from the central direction of the chamber housing 110 to one side direction.

The second injection hole may be formed to be twisted at the third angle θ₃ from the central direction of the chamber housing 110 to the other side direction. Therefore, the second injection hole may inject the etch gas in the direction away from the center of the inside of the chamber housing 110, but the invention is not limited thereto, and the second injection hole may be rotatably formed to be twisted at the third angle θ₃ from the central direction of the chamber housing 110 to the other side direction.

The first gas injector 210 may be provided as a 2-way 2-hole nozzle, thereby improving concentration uniformity of the etch gas in the chamber housing 110. In addition, as the first gas injector 210 is provided as a 2-way 2-hole nozzle, a flow rate may be improved so that the speed of airflow in the chamber housing 110 is increased.

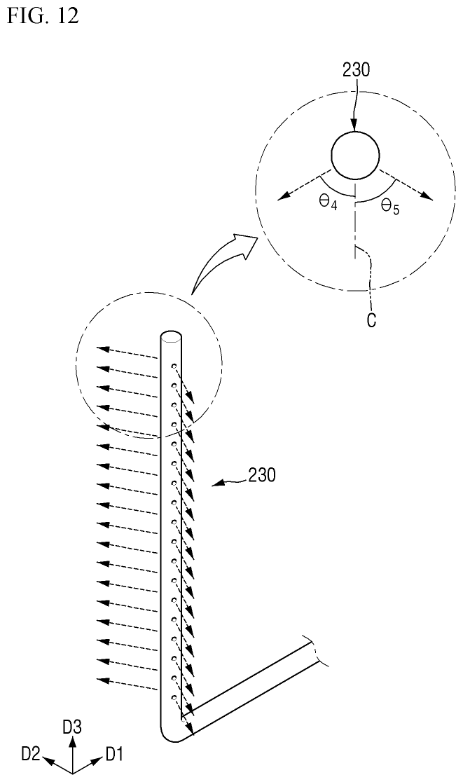

Next, a case that the first gas injector 210 is provided as a 2-way multi-hole nozzle will be described. FIG. 12 is a third exemplary view illustrating various structures of a first gas injector constituting a process chamber cleaning apparatus.

The first gas injector 210 may include a plurality of first injection holes and a plurality of second injection holes. The plurality of first injection holes may inject the etch gas in the same direction in the chamber housing 110. The plurality of first injection holes may inject the etch gas in the direction (e.g., a first direction) away from the center of the inside of the chamber housing 110 from a surface of a body of the first gas injector 210. The plurality of first injection holes may inject the etch gas in a direction twisted at a fourth angle θ₄ in one direction from the central direction C of the inside of the chamber housing 110.

The plurality of second injection holes may inject the etch gas in the same direction in the chamber housing 110. The plurality of second injection holes may inject the etch gas in the direction (e.g., a second direction opposite to the first direction) away from the center of the inside of the chamber housing 110 from the surface of the body of the first gas injector 210. The plurality of second injection holes may inject the etch gas in the direction twisted at a fifth angle θ₅ in a direction different from the plurality of first injection holes from the central direction C of the inside of the chamber housing 110.

The fourth angle θ₄ and the fifth angle θ₅ may be greater than 0° and smaller than 90°. Preferably, the fourth angle θ₄ and the fifth angle θ₅ may be greater than 45° and smaller than 90°. More preferably, the fourth angle θ₄ and the fifth angle θ₅ may be greater than 60° and smaller than 80°. More preferably, the fourth angle θ₄ and the fifth angle θ₅ may be 70°. The fourth angle 04 and the fifth angle θ₅ may be the same value, but the invention is not limited thereto, and the fourth angle θ₄ and the fifth angle θ₅ may be different values.

The plurality of first injection holes may be arranged in a height direction (third direction D3) of the chamber housing 110 on the surface of the body of the first gas injector 210. Each of the first injection holes may be formed to be twisted at the fourth angle θ₄ from the central direction of the chamber housing 110 to one side direction (e.g., a first direction). Therefore, the plurality of first injection holes may inject the etch gas in the direction away from the center of the inside of the chamber housing 110, but the invention is not limited thereto, and each of the first injection holes may be rotatably formed to be twisted at the fourth angle 04 from the central direction of the chamber housing 110 to one side direction.

The plurality of second injection holes may be arranged in the height direction (third direction D3) of the chamber housing 110 on the surface of the body of the first gas injector 210. Each of the second injection holes may be formed to be twisted at the fifth angle θ₅ from the central direction of the chamber housing 110 to the other side direction (e.g., a second direction opposite to the first direction). Therefore, the plurality of second injection holes may inject the etch gas in the direction away from the center of the inside of the chamber housing 110, but the invention is not limited thereto, and each of the second injection holes may be rotatably formed to be twisted at the fifth angle θ₅ from the central direction of the chamber housing 110 to the other side direction.

The first gas injector 210 may be provided as a 2-way multi-hole nozzle, thereby improving concentration uniformity of the etch gas in the chamber housing 110. In addition, as the first gas injector 210 is provided as a 2-way multi-hole nozzle, a flow rate may be improved so that the speed of airflow in the chamber housing 110 is increased.

The first gas injector 210 may inject the etch gas into the inner space of the chamber housing 110 in order to remove the reactant deposited on the inner wall or the component of the process chamber. In this case, the first gas injector 210 may inject the etch gas in a state that its position is fixed at one side of the inside of the chamber housing 110. For example, when an inner area of the chamber housing 110 is divided into a top zone, a middle zone, and a bottom zone in the vertical direction D3, the first gas injector 210 may inject the etch gas into only the bottom zone. For example, the vertical level of the middle zone may be higher than the vertical level of the bottom zone and lower than the vertical level of the top zone. However, when the first gas injector 210 operates in one-system supply manner as described above (e.g., using a single injection operation), non-uniform etching may occur for each zone.

In order to solve such a problem in the present disclosure, the first gas injector 210 may operate in an N-system sequential supply method. That is, the first gas injector 210 may sequentially select a plurality of zones in the chamber housing 110 to inject the etch gas to each zone at a time difference. The plurality of zones may be divided along the height direction of the chamber housing 110. For example, the first gas injector may be configured to inject the etch gas to a first zone of the chamber housing at a first time and inject the etch gas to a second zone of the chamber housing at a second time different from the first time.

For example, when operating in a three-system sequential supply method, the first gas injector 210 may inject the etch gas into any one of the top zone, the middle zone and the bottom zone at the early period, the first gas injector 210 may inject the etch gas into another one of the top zone, the middle zone and the bottom zone at the middle period, and the first gas injector 210 may inject the etch gas into other one of the top zone, the middle zone and the bottom zone at the end period. Preferably, the first gas injector 210 may inject the etch gas into the bottom zone at the early period, the first gas injector 210 may inject the etch gas into the middle zone at the middle period, and the first gas injector 210 may inject the etch gas into the top zone at the end period.

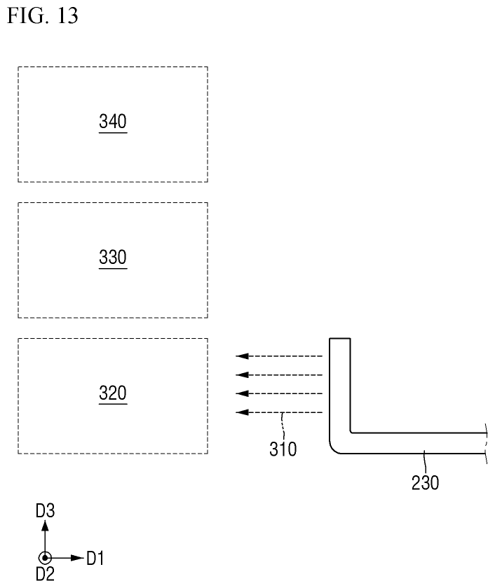

When the first gas injector 210 is provided as a spiral nozzle or a 2-way 2-hole nozzle, the first gas injector 210 may inject the etch gas while being elevated in the chamber housing 110. Referring to the example of FIG. 13, the first gas injector 210 may inject etch gas 310 into a bottom zone 320. FIG. 13 is a first exemplary view illustrating an operating method of a first gas injector when a first gas injector has a structure according to the first embodiment.

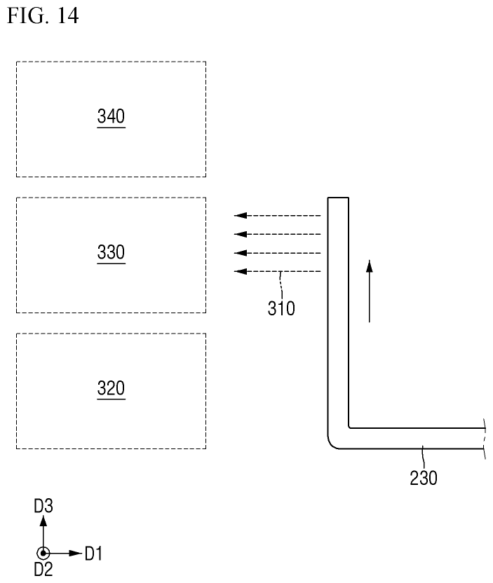

Subsequently, referring to the example of FIG. 14, after a predetermined time passes, the first gas injector 210 may inject the etch gas 310 into the middle zone 330. The first gas injector 210 may be elevated at a predetermined height in the chamber housing 110 to inject the etch gas 310 into the middle zone 330. For example, the first gas injector may be elevated by a motor, an actuator, or the like. Although the first gas injector 210 may continuously inject the etch gas 310 while being elevated, the invention is not limited thereto, and the first gas injector 210 may not inject the etch gas 310 while being elevated. FIG. 14 is a second exemplary view illustrating an operating method of a first gas injector when a first gas injector has a structure according to the first embodiment.

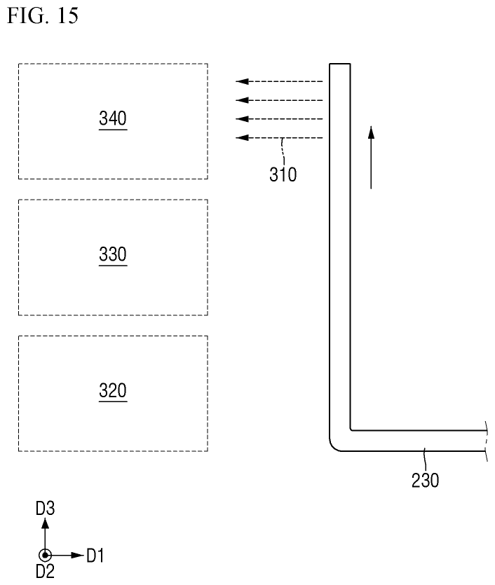

Subsequently, referring to the example of FIG. 15, after a predetermined time passes, the first gas injector 210 may inject the etch gas 310 into the top zone 340. The first gas injector 210 may be elevated at a predetermined height in the chamber housing 110 to inject the etch gas 310 into the top zone 340. Although the first gas injector 210 may continuously inject the etch gas 310 while being elevated, the invention is not limited thereto, and the first gas injector 210 may not inject the etch gas 310 while being elevated. FIG. 15 is a third exemplary view illustrating an operating method of a first gas injector when the first gas injector has a structure according to the first embodiment.

The first gas injector 210 may inject the etch gas 310 while being elevated as described with reference to FIGS. 13 to 15, thereby enabling uniform etching for each zone in the chamber housing 110.

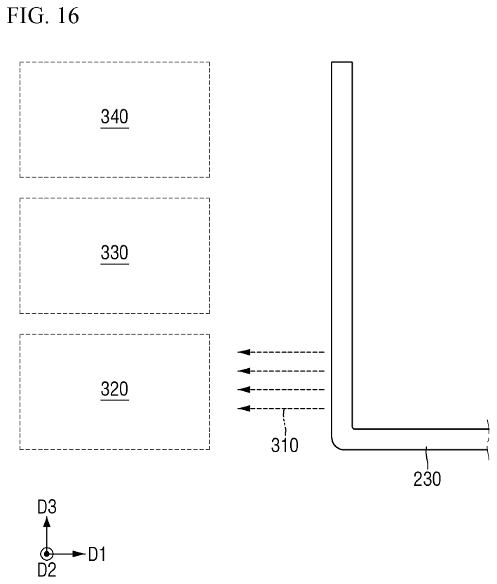

When the first gas injector 210 is provided as a 2-way multi-hole nozzle, the first gas injector 210 may inject the etch gas while selectively operating the plurality of first injection holes and the plurality of second injection holes. Referring to the example of FIG. 16, some of the first injection holes installed at a position corresponding to the bottom zone 320 may inject the etch gas 310 into the bottom zone 320. In addition, some of the second injection holes installed at a position corresponding to the bottom zone 320 may inject the etch gas 310 into the bottom zone 320. FIG. 16 is a first exemplary view illustrating an operating method of a first gas injector when a first gas injector has a structure according to the second embodiment.

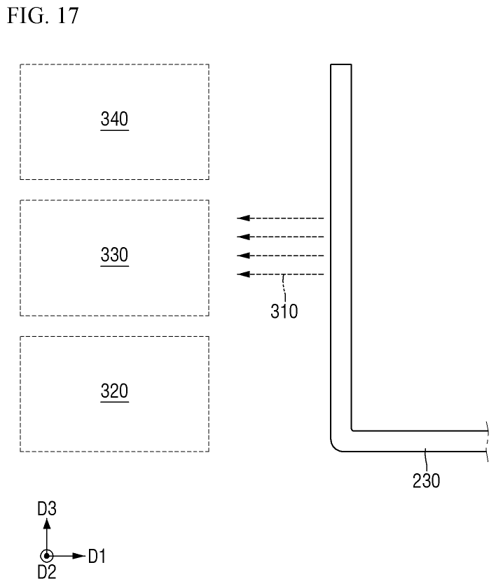

Subsequently, referring to the example of FIG. 17, after a predetermined time passes, some of the first injection holes installed at a position corresponding to the middle zone 330 may inject the etch gas 310 into the middle zone 330. In addition, some of the second injection holes installed at a position corresponding to the middle zone 330 may inject the etch gas 310 into the middle zone 330. FIG. 17 is a second exemplary view illustrating an operating method of a first gas injector when a first gas injector has a structure according to the second embodiment.

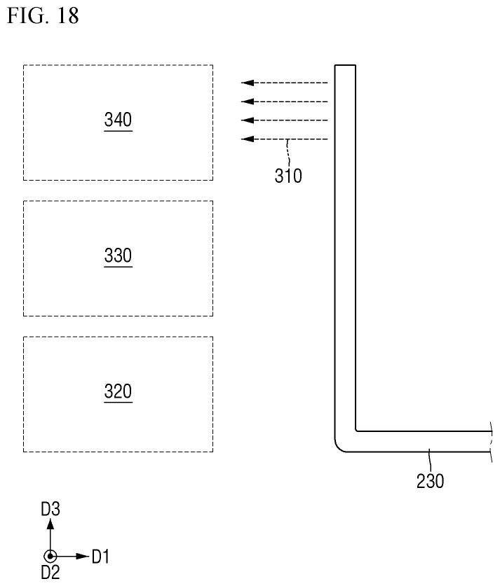

Subsequently, referring to the example of FIG. 18, after a predetermined time passes again, some of the first injection holes installed at a position corresponding to the top zone 340 may inject the etch gas 310 into the top zone 340. In addition, some of the second injection holes installed at a position corresponding to the top zone 340 may inject the etch gas 310 into the top zone 340. FIG. 18 is a third exemplary view illustrating an operating method of a first gas injector when a first gas injector has a structure according to the second embodiment.

The first gas injector 210 may inject the etch gas 310 while selectively operating the plurality of first injection holes and the plurality of second injection holes as described with reference to FIGS. 16 to 18, thereby enabling uniform etching for each zone in the chamber housing 110.

In the above description, the case that a single first gas injector 210 is provided in the process chamber cleaning apparatus 100 has been described, but the invention is not limited thereto, and a plurality of first gas injectors 210 may be provided in the process chamber cleaning apparatus 100. For example, three first gas injectors 210 may be provided in the process chamber cleaning apparatus 100.

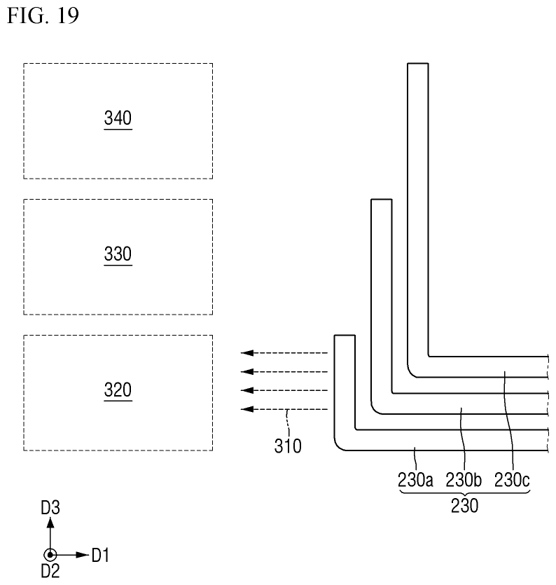

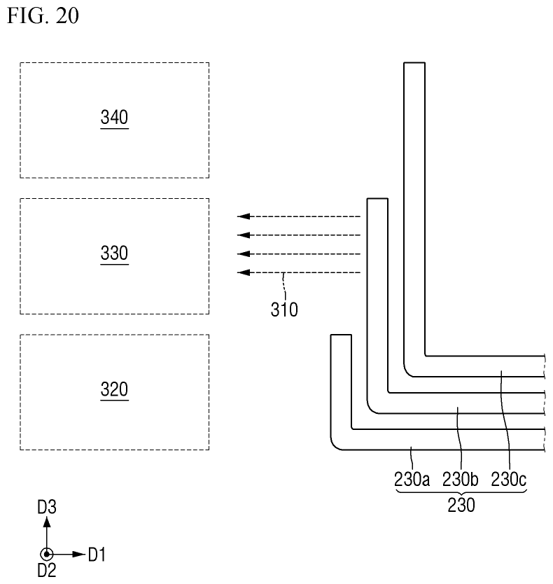

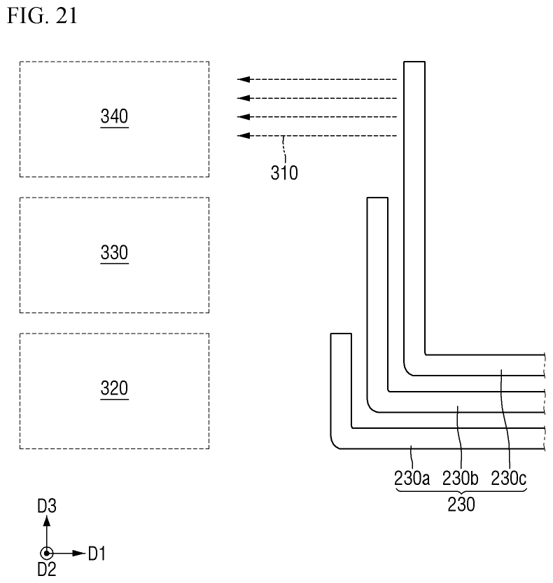

FIG. 19 is a first exemplary view illustrating an operating method of a first gas injector when the first gas injector has a structure according to the third embodiment. FIG. 20 is a second exemplary view illustrating an operating method of a first gas injector when the first gas injector has a structure according to the third embodiment. FIG. 21 is a third exemplary view illustrating an operating method of a first gas injector when the first gas injector has a structure according to the third embodiment.

When the first gas injector 210 is provided as a spiral nozzle or a 2-way 2-hole nozzle, the first gas injector 210 may include three injectors such as an (a)th injector 230a, a (b)th injector 230b and a (c)th injector 230c. The (a)th injector 230a, the (b)th injector 230b and the (c)th injector 230c may include first injection holes installed at positions corresponding to different zones. Alternatively, the (a)th injector 230a, the (b)th injector 230b and the (c)th injector 230c may each include a first injection hole and a second injection hole, which are installed at positions corresponding to different zones. For example, the (a)th injector 230a may include at least one injection hole installed at a position corresponding to the bottom zone 320, the (b)th injector 230b may include at least one injection hole installed at a position corresponding to the middle zone 330, and the (c)th injector 230c may include at least one injection hole installed at a position corresponding to the top zone 340.

First, referring to the example of FIG. 19, the (a)th injector 230a may inject the etch gas 310 into the bottom zone 320. Subsequently, referring to the example of FIG. 20, after a predetermined time passes, the (b)th injector 230b may inject the etch gas 310 into the middle zone 330. Subsequently, referring to the example of FIG. 21, after a predetermined time passes, the (c)th injector 230c may inject the etch gas 310 into the top zone 340.

The first gas injector 210 may inject the etch gas 310 while selectively operating the (a)th injector 230a, the (b)th injector 230b and the (c)th injector 230c as described with reference to FIGS. 19 to 21, thereby enabling uniform etching for each zone in the chamber housing 110.

The internal structure and various embodiments of the process chamber cleaning apparatus 100 have been described with reference to FIGS. 1 to 21. The present disclosure relates to an apparatus and a method for removing a thin film in a batch type facility by using in-situ gas treatment. According to the present disclosure, a facility automation function using the controller 180 is applied, and an entire process may be automatically performed under the control of the controller 180 without intervention of an engineer. According to the present disclosure, a work environment may be provided so that a field direct work time of a facility engineer may be reduced to allow the facility engineer to be concentrated on a source improvement work, and a foundation capable of improving a technical capability of the facility engineer may be constructed.

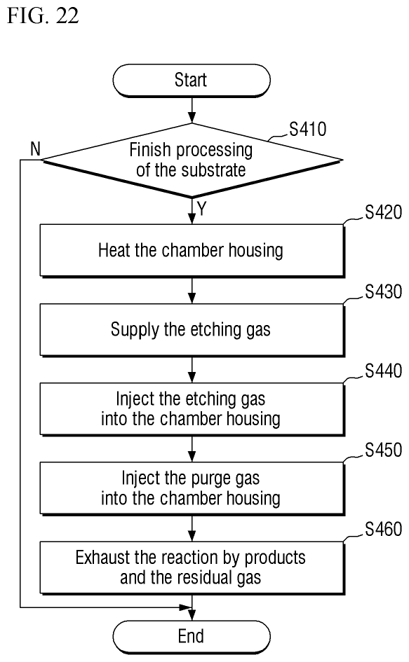

Next, a process chamber cleaning method of the process chamber cleaning apparatus 100 will be described. FIG. 22 is a flow chart sequentially illustrating a process chamber cleaning method of a process chamber cleaning apparatus.

As described above, the process chamber cleaning apparatus 100 may deposit a material film on the semiconductor substrate W, thereby depositing a reactant on the inner wall or the component of the process chamber cleaning apparatus 100. The process chamber cleaning apparatus 100 may start a work of removing the reactant deposited on the inner wall or the component when the deposition process for the semiconductor substrate W is terminated. The process chamber cleaning apparatus 100 may be constructed as a fully automated system under the control of the controller 180.

When the deposition process for the semiconductor substrate W is completed (S410), the gas supply 140 may provide the etch gas into the first gas injector 210 (S430), and the first gas injector 210 may inject the etch gas provided by the gas supply 140 into the inside of the chamber housing 110 (S440). The first gas injector 210 may inject the etch gas containing ClF₃ component into the inside of the chamber housing 110.

The first gas injector 210 may be provided in the form of a spiral nozzle, a 2-way 2-hole nozzle, a 2-way multi-hole nozzle and the like to inject the etch gas into the inside of the chamber housing 110. The first gas injector 210 may be provided in the form of a 2-way 2-hole nozzle in order to improve concentration uniformity in the chamber housing 110 and improve the speed of airflow in the chamber housing 110 at the same time.

The first gas injector 210 may perform uniform etching for each zone by operating in a three-system sequential supply method. For example, the first gas injector 210 may inject the etch gas into the bottom zone 320 at the early period, may inject the etch gas into the middle zone 330 at the middle period, and may inject the etch gas into the top zone 340 at the end period.

The etch gas injected by the first gas injector 210 may react with the reactant deposited on the inner wall of the chamber housing 110 or the component (for example, the substrate support 120, the first gas injector 210, etc.) positioned in the chamber housing 110 to remove the reactant. Energy may be supplied to the etch gas to expedite reaction between the etch gas and the reactant. The heating unit 130 may maintain the internal temperature of the chamber housing 110 at 250° C. in consideration of both the ISD process temperature and the ISD process time. This operation of the heating unit 130 may be performed before the gas supply 140 provides the etch gas to the first gas injector 210 (S420), but the invention is not limited thereto, and the operation of the heating unit 130 may be performed simultaneously with the operation of the first gas injector 210.

After a predetermined time passes, the fourth gas injector 240 may inject purge gas for purifying the inside of the chamber housing 110 into the chamber housing 110 (S450). When the etch gas remains in the chamber housing 110 after the etch gas injection step S440, the etch gas may etch the reactant deposited on the semiconductor substrate W, whereby a deposition process defect of the semiconductor substrate W may be caused. To prevent the deposition process defect, the purge gas injected by the fourth gas injector 240 may be chemical gas capable of removing the etch gas by reacting with the etch gas.

After a predetermined time passes again, the gas discharge unit 160 may discharge reaction by-products or the etch gas, the purge gas, etc., which remain in the chamber housing 110, to the outside (S460). In the present disclosure, the step S450 may be omitted, and the step S460 may be performed subsequently to the step S440. Alternatively, after the step S460 is performed subsequently to the step S440, the step S450 and the step S460 may be sequentially performed.

Example embodiments of the present disclosure have been described hereinabove with reference to the accompanying drawings, but the invention is not limited to the above-described example embodiments, and may be implemented in various different forms, and one of ordinary skill in the art to which the present disclosure pertains may understand that the present disclosure may be implemented in other specific forms without changing the technical concept or features of the present disclosure. Therefore, it is to be understood that the example embodiments described above are illustrative rather than being restrictive in all aspects.

1. A process chamber cleaning apparatus comprising:
a chamber housing;
a substrate support inside the chamber housing, the substrate support being configured to support a plurality of semiconductor substrates;
a gas supply configured to provide process gases;
a first gas injector inside the chamber housing and connected to the gas supply, the first gas injector being configured to inject an etch gas, which is one of the process gases, into the chamber housing; and
a controller configured to control operations of the gas supply and the first gas injector,
wherein the first gas injector is configured to inject the etch gas in a direction twisted at a predetermined angle from a central direction of the chamber housing, the central direction being a horizontal direction from the first gas injector to the center of the chamber housing.

2. The process chamber cleaning apparatus of claim 1, wherein the first gas injector is configured to inject the etch gas in a state that the substrate support is not separated from the process chamber cleaning apparatus.

3. The process chamber cleaning apparatus of claim 1, wherein the process chamber cleaning apparatus is configured to increase a frequency of occurrence of a first reaction so that the frequency of occurrence of the first reaction is higher than a frequency of occurrence of a second reaction,
the first reaction is between the etch gas and a reactant deposited on at least one of an inner wall of the chamber housing and a surface of the substrate support, and
the second reaction includes at least one of a reaction between the etch gas and the chamber housing and a reaction between the etch gas and the substrate support.

4. The process chamber cleaning apparatus of claim 3, wherein the etch gas includes a ClF₃ component.

5. The process chamber cleaning apparatus of claim 3, further comprising a heater configured to heat the chamber housing to adjust an internal temperature of the chamber housing,
wherein the heater is configured to adjust the internal temperature of the chamber housing to reach 150° C. to 250° C.

6. The process chamber cleaning apparatus of claim 3, wherein a ratio between the frequency of occurrence of the second reaction and the frequency of occurrence of the first reaction is between 1/100 and 1/300.

7. The process chamber cleaning apparatus of claim 1, wherein the first gas injector includes a first injection hole, and
the first injection hole is formed to be twisted at the predetermined angle from the central direction of the chamber housing.

8. The process chamber cleaning apparatus of claim 1, wherein the first gas injector includes a first injection hole and a second injection hole,
the first injection hole is formed to be twisted at the predetermined angle from the central direction of the chamber housing in a first direction, and
the second injection hole is formed to be twisted at the predetermined angle from the central direction of the chamber housing in a second direction opposite to the first direction.

9. The process chamber cleaning apparatus of claim 1, wherein the first gas injector includes a plurality of first injection holes and a plurality of second injection holes,
the plurality of first injection holes are arranged in a height direction of the chamber housing, and each of the first injection holes is formed to be twisted at the predetermined angle from the central direction of the chamber housing in a first direction, and
the plurality of second injection holes are arranged in a height direction of the chamber housing, and each of the second injection holes is formed to be twisted at the predetermined angle from the central direction of the chamber housing to a second direction opposite to the first direction.

10. The process chamber cleaning apparatus of claim 1, wherein the first gas injector is configured to inject the etch gas to a first zone of the chamber housing at a first time and inject the etch gas to a second zone of the chamber housing at a second time different from the first time.

11. The process chamber cleaning apparatus of claim 10, wherein the first zone is at a lower vertical level in the chamber housing than a vertical level of the second zone.

12. The process chamber cleaning apparatus of claim 10, wherein
the first gas injector is configured to inject the etch gas into the first zone, inject the etch gas into the second zone, and then inject the etch gas into a third zone at a higher vertical level than the vertical level of the second zone.

13. The process chamber cleaning apparatus of claim 10, wherein the first gas injector is elevated to inject the etch gas.

14. The process chamber cleaning apparatus of claim 10, wherein the first gas injector includes a first injection hole at a position corresponding to the first zone and a second injection hole at a position corresponding to the second zone.

15. The process chamber cleaning apparatus of claim 10, wherein the first gas injector includes a first part and a second part,
the first part includes a first injection hole installed at a position corresponding to the first zone, and
the second part includes a second injection hole installed at a position corresponding to the second zone.

16. The process chamber cleaning apparatus of claim 1, further comprising:
a second gas injector inside the chamber housing and connected to the gas supply, the second gas injector being configured to inject a source gas, which is one of the process gases, into the chamber housing; and
a third gas injector inside the chamber housing and connected to the gas supply, the third gas injector being configured to inject a reaction gas, which is one of the process gases, into the chamber housing,
wherein the first gas injector is configured to operate subsequently to an operation of the second gas injector and an operation of the third gas injector.

17. The process chamber cleaning apparatus of claim 16, further comprising a fourth gas injector inside the chamber housing and connected to the gas supply, the fourth gas injector being configured to inject a purge gas, which is one of the process gases, into the chamber housing,
wherein the fourth gas injector is configured to operate subsequently to the operation of the first gas injector.

18. A process chamber cleaning method comprising:
after a process of depositing a material film on a substrate is terminated, heating a chamber housing using a heating unit to adjust an internal temperature of the chamber housing; and
providing an etch gas to the inside of the chamber housing using a first gas injector,
wherein the first gas injector provides the etch gas in a direction twisted at a predetermined angle from a central direction of the chamber housing the central direction being a horizontal direction from the first gas injector to the center of the chamber housing.

19. The process chamber cleaning method of claim 18, further comprising:
providing, to the inside of the chamber housing using a second gas injector, a purge gas for removing the etch gas; and
discharging reaction by-products and gas, which remain in the inside of the chamber housing, to the outside to the outside of the chamber housing.

20. A process chamber cleaning apparatus comprising:
a chamber housing;
a heating unit configured to heat the chamber housing to adjust an internal temperature of the chamber housing;
a substrate support inside the chamber housing, the substrate support being configured to support a plurality of substrates;
a gas supply configured to provide process gasses;
a first gas injector inside the chamber housing and connected to the gas supply, the first gas injector being configured to inject an etch gas, which is one of the process gases, into the inside of the chamber housing; and
a controller configured to control operations of the gas supply and the first gas injector,
wherein the first gas injector is configured to inject the etch gas in a direction twisted at a predetermined angle from a central direction of the chamber housing, the central direction being a horizontal direction from the first gas injector to the center of the chamber housing,
the first gas injector is configured to inject the etch gas in a state that the substrate support is not separated from the process chamber cleaning apparatus,
the first gas injector is configured to inject the etch gas to a first zone of the chamber housing at a first time and inject the etch gas to a second zone of the chamber housing at a second time different from the first time,
the etch gas includes a ClF₃ component, and
the heating unit is configured to adjust the internal temperature of the chamber housing to reach 150° C. to 250° C.

21-23. (canceled)
